(19) United States
(12) Patent Application Publication
(10) Pub. No.: US 2007/0020796 A1
(43) Pub. Date: Jan. 25, 2007

(54) Image sensor having multi-gate insulating layers and fabrication method

(76) Inventor: Young-Hoon Park, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/437,682

(22) Filed: May 22, 2006

(30) Foreign Application Priority Data
Jul. 19, 2005 (KR) 2005-0065442

(51) Int. Cl. H01L 21/00

(52) U.S. Cl. 438/57

(57) ABSTRACT

An image sensor and related method of fabrication are disclosed. The image sensor includes a first gate insulating layer of first material layer type disposed in a sensor region of a semiconductor substrate, a second gate insulating layer of second material layer type disposed in an analog region of the semiconductor substrate, and a third gate insulating layer of third material layer type disposed in a digital region of the semiconductor substrate, wherein the first, second, and third material layer types are disparate in nature.

### BACKGROUND OF THE INVENTION

1. Technical Field

Embodiments of the invention relate to an image sensor and a related method of fabrication. More particularly, embodiments of the invention relate to a complementary metal oxide semiconductor (CMOS) image sensor having multi-gate insulating layers and a related method of fabrication.

This application claims priority from Korean Patent Application No. 10-2005-0065442, filed Jul. 19, 2005, the disclosure of which is hereby incorporated herein by reference in its entirety as if set forth fully herein.

2. Discussion of the Related Art

An image sensor is a device that converts optical energy into electrical signals. Recently, the commercial demand for high performance image sensors has increased due to the popularity of various systems such as digital cameras, video recorders, personal communication systems (PCS), game devices, medical micro-camera systems, robots, etc.

Recent technical developments have enabled the fabrication of a semiconductor integrated circuit device employing the image sensor in the form of a system on chip. This system on chip comprises a digital circuit, an analog circuit, and an image sensing circuit all integrated on a single semiconductor substrate.

FIG. 1 is a sectional view illustrating a conventional image sensor.

Referring to FIG. 1, an image sensor is provided on a semiconductor substrate 100. The image sensor includes a sensor region having an image sensing circuit as well as a peripheral circuit region having a digital circuit and an analog circuit.

An isolation layer 110 is provided at predetermined intervals on semiconductor substrate 100 to define active regions. A photodiode 120 and a hole accumulation device (HAD) 130 are provided in the active region of the sensor region. Photodiode 120 receives external lights to generate photo current and HAD 130 reduces dark current from photo diode 120. A gate oxide layer 140 is formed on the active region, and gate patterns 150 are formed on gate oxide layer 140 in the sensor region and the peripheral circuit region. Spacers 160 are formed on sidewalls of gate patterns 150. Impurity ions are implanted into the active regions using gate patterns 150 and spacers 160 as ion implantation masks, thereby forming source/drain regions 170.

When a design rule for the image sensor is equal to or greater than about 0.2 micrometer (μm), a pure silicon oxide layer may be used as gate oxide layer 140. However, when the design rule is reduced and transistors are scaled down, the thickness of gate oxide layer 140 must also be decreased. In such cases, leakage current may flow and thereby degrade the reliability of gate oxide layer 140. In order to prevent degradation of gate oxide layer 140, a silicon oxynitride layer or a high-k dielectric layer may be employed instead of a silicon oxide layer. In the event that a silicon oxynitride layer or a high-k dielectric layer is used to form gate oxide layer 140, the reliability of transistors formed in the peripheral circuit region may be improved, but the electrical performance characteristics of transistors formed in the sensor region may be degraded. This unfortunate result is due to interface charges that develop in the gate dielectric layer of the sensor region. These interface charges generate noise and degrade resolution of the image sensor.

One conventional method of fabricating the image sensor is disclosed in U.S. patent publication No. US 2003/0173585 A1, the subject matter of which is hereby incorporated by reference.

### SUMMARY OF THE INVENTION

In one embodiment, the invention provides an image sensor comprising; a first gate insulating layer of first material layer type disposed in a sensor region of a semiconductor substrate, a second gate insulating layer of second material layer type disposed in an analog region of the semiconductor substrate, and a third gate insulating layer of third material layer type disposed in a digital region of the semiconductor substrate, wherein the first, second, and third material layer types are disparate.

In another embodiment, the invention provides a method of fabricating an image sensor, comprising: forming a first gate insulating layer on a substrate, forming a first gate conductive layer pattern on the first gate insulating layer in a sensor region of the substrate, selectively removing the first gate insulating layer from a digital region of the substrate, forming an additional gate insulating layer on the substrate where the first gate insulating layer has been selectively removed from the digital region of the substrate, wherein the first gate insulating layer and the additional gate insulating layer in an analog region of the substrate form a second gate insulating layer, and the additional gate insulating layer in the digital region of the substrate form a third gate insulating layer; and forming a second gate conductive layer pattern to cover the additional gate insulating layer in the analog and digital regions.

### BRIEF DESCRIPTION OF THE DRAWINGS

FIG. 1 is a sectional view illustrating a conventional image sensor;

FIG. 2 is a block diagram illustrating an image sensor according to an embodiment of the present invention;

FIG. 3 is a sectional view illustrating an image sensor according to an embodiment of the present invention; and

FIGS. 4 through 13 are sectional views illustrating a method of fabricating an image sensor according to an embodiment of the present invention.

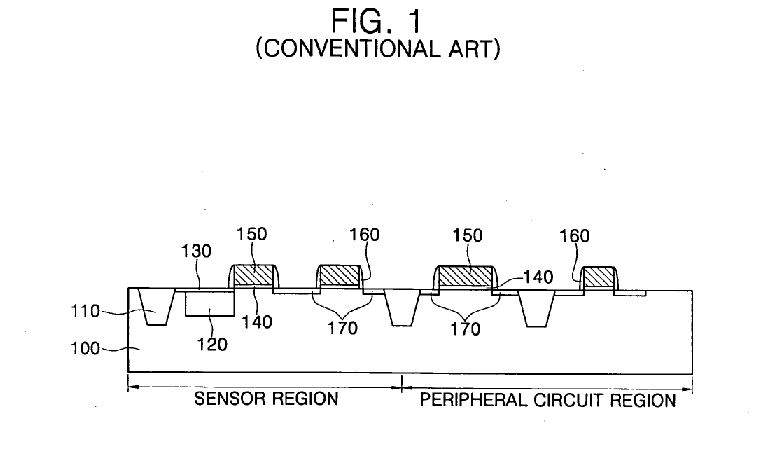

### DESCRIPTION OF EXEMPLARY EMBODIMENTS

Several embodiments of the invention will now be described with reference to the accompanying drawings. The invention may, however, be embodied in many different forms and should not be construed as being limited to only the embodiments set forth herein. Rather, these embodiments are presented as teaching examples. Like numbers refer to like elements throughout the specification.

Semiconductor integrated circuit devices according to embodiments of the invention may include a charge coupled device (CCD) or a complementary metal oxide semiconductor (CMOS) image sensor. While the CCD has advantages of low noise and excellent image quality, it needs a high operating voltage and high processing costs. The CMOS image sensor can be fabricated in a single chip together with a signal processing circuit. Thus, it is possible to scale down the CMOS image sensor. Further, the CMOS image sensor can be fabricated using a conventional CMOS process technology. Accordingly, manufacturing costs of the CMOS image sensor can be reduced. Furthermore, the CMOS image sensor may exhibit low power consumption, since the CMOS image sensor employs CMOS circuits. Therefore, the CMOS image sensor may be widely employed in a portable electronic system and/or a mobile communication system. Hereinafter, although the invention is described in conjunction with the CMOS image sensor, the present invention may be applicable to the CCD.

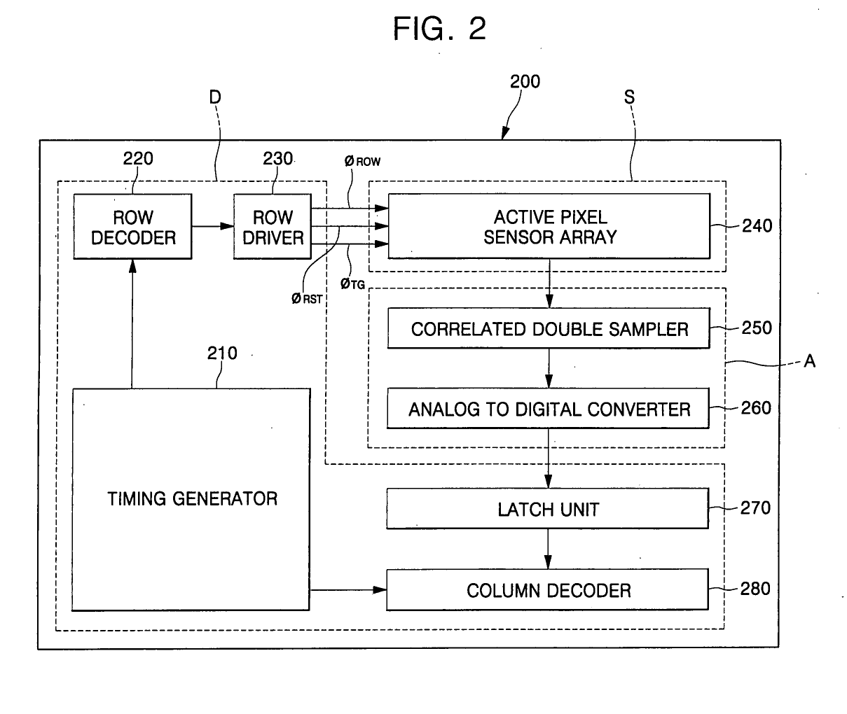

FIG. 2 is a block diagram illustrating an image sensor according to an embodiment of the invention.

Referring to FIG. 2, exemplary image sensor 200 generally comprises a sensor region S, a digital region D and an analog region A. Sensor region S may comprise an active pixel sensor array (APS array) 240. Digital region D may comprise digital circuits such as a timing generator 210, a row decoder 220, a row driver 230, a latch unit 270, and a column decoder 280. Further, analog region A may comprise analog circuits such as a correlated double sampler (CDS) 250, and an analog-to-digital converter (ADC) 260.

Active pixel sensor array 240 may comprise a plurality of two-dimensionally arranged unit pixels. The unit pixels are adapted to convert optical energy (e.g., visible light) into electrical signals. Active pixel sensor array 240 receives various input signals such as a pixel select signal φROW, a reset signal φRST and a charge transfer signal φTG from row driver 230. Further, the electrical signals output from APS array 240 are transmitted to CDS 250 through vertical signal lines.

Timing generator 210 is adapted to supply a timing signal and a control signal to both of row decoder 220 and column decoder 280.

Row driver 230 is adapted to generate the input signals φROW, φRST and φTG according to output signals provided by row decoder 220, and the input signals φROW, φRST and φTG are supplied to APS array 240 as described above. In general, when unit pixels are arrayed in a matrix shape, the input signals φROW, φRST and φTG are applied to each row of APS array 240.

In the illustrated embodiment, CDS 250 receives an electrical signal generated from APS array 240 through a vertical signal line, and CDS 250 holds and samples the output electrical signal of APS array 240. That is, CDS 250 samples a specific reference voltage level (hereinafter, referred to as “noise level”) and a voltage level of the output electrical signal (hereinafter, referred to as “signal level”) of APS array 240, thereby outputting a difference level between the noise level and the signal level.

ADC 260 is adapted to convert an analog signal corresponding to the difference level between the noise level and the signal level into a digital signal.

Latch unit 270 is adapted to latch the digital signal from ADC 260, such that the latched signal may be transmitted to an image signal processor (ISP; not shown) in accordance with the decoding results provided by column decoder 280.

Image sensor 200 and the corresponding ISP may be mounted on a single chip. In this case, the ISP and a memory device associated with the ISP may be provided in digital region D. The memory device associated with the ISP may be a static random access memory (SRAM) or a read only memory (ROM), for example.

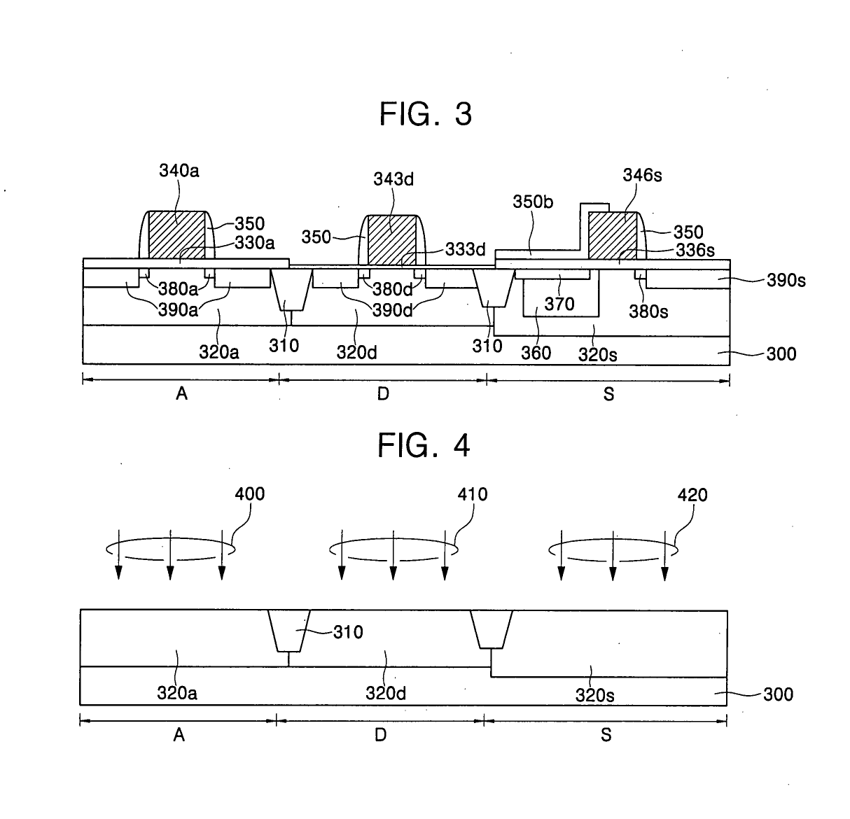

FIG. 3 is a sectional view illustrating an image sensor according to an embodiment of the invention. Referring to FIG. 3, an isolation layer 310 is provided in a predetermined region of a semiconductor substrate 300 to define active regions. Semiconductor substrate 300 has an analog region A, a digital region D and a sensor region S. Wells are provided in semiconductor substrate 300 in relation to isolation layer 310. The wells may include an analog circuit well 320a formed in analog region A, a digital circuit well 320d formed in digital region D and a sensor well 320s formed in sensor region S.

Analog circuit well 320a and digital circuit well 320d may be either n-type or p-type. For example, a p-type well may be provided in a region where an NMOS transistor to be formed, and an n-type well may be provided in a region where a PMOS transistor to be formed, as determined by a specific design.

In the illustrated embodiment, sensor well 320s is p-type, because the transistors to be formed in sensor region S are NMOS transistors and electrons are used as signal transfer charges. The signal transfer charges are generated in proportion to the intensity of the received optical energy. Impurity regions may be additionally provided at the respective surfaces of the active regions to adjust for a threshold voltage, as determined by a specific design.

A first gate insulating layer 336s is provided on semiconductor substrate 300 in sensor region S, and a second gate insulating layer 330a is provided on semiconductor substrate 300 in analog region A. First gate insulating layer 336s may be a silicon oxide layer, and second gate insulating layer 330a may be a combination layer of a silicon oxide layer and a silicon oxynitride layer. In addition, a third gate insulating layer 333d is provided on semiconductor substrate in digital region D. Third gate insulating layer 336d may be composed of only a silicon oxynitride layer. Thus, according to these embodiment variations, first through third gate insulating layers 336s, 330a and 333d may be different material layers from each other.

Third gate insulating layer 333d may be thinner than first gate insulating layer 336s and second gate insulating layer 330a. Further, first and second gate insulating layers 336s and 330a may have substantially the same thickness. Alternatively, second gate insulating layer 330a may be thicker than first gate insulating layer 336s. Further, the thickness of second gate insulating layer 330a may range from between about two to four times the thickness of third gate insulating layer 333d. For example, in one embodiment, first gate insulating layer 336s has a thickness of about 60 Å to 75 Å, second gate insulating layer 330a has a thickness of about 50 Å to 80 Å, and third gate insulating layer 333d has a thickness of about 20 Å or the less.

First through third gate patterns 346s, 340a and 343d are provided on first through third gate insulating layers 336s, 330a and 333d, respectively. First gate pattern 346a is disposed to cross over the active region in sensor region S, and second gate pattern 340a is disposed to cross over the active region in analog region A. Further, third gate pattern 343d is disposed to cross over the active region in digital region D.

Second gate pattern 340a in analog region A may have a greater width than that of third gate pattern 343d in digital region D. For example, in one embodiment drawn to an image sensor formed with a design rule of 0.15 μm, third gate pattern 343d has a width of about 0.15 μm, and second gate pattern 340a has a width of about 0.25 μm or the greater.

A photo diode region 360 is provided in the active region of sensor region S. Photo diode region 360 is disposed adjacent to one sidewall of first gate pattern 346s. In addition, a hole accumulation device (HAD) region 370 is provided in photo diode region 360. In one embodiment, photo diode region 360 may be an n-type impurity region, and HAD region 370 may be a p-type impurity region.

In the illustrated embodiment, spacers 350 are provided on sidewalls of first through third gate patterns 346s, 340a and 343d. Further, HAD region 370 may be covered with a blocking layer 350b. Blocking layer 350b may extend to cover a sidewall of first gate pattern 346s, which is adjacent to HAD region 370. Blocking layer 350b may formed from the same material layer as spacers 350. For example, the blocking layer 350b and the spacers 350 may be from a silicon nitride layer.

A low concentration source/drain region 380s and a high concentration source/drain region 390s are provided in the active region adjacent to first gate pattern 346s and opposite HAD region 370. Low concentration source/drain region 380s is self-aligned with first gate pattern 380s, and high concentration source/drain region 390s is self-aligned with the outer sidewall of spacer 350 formed on the sidewall of first gate pattern 346s. As a result, low concentration source/drain region 380s is disposed below spacer 350 formed on the sidewall of first gate pattern 346s.

Further, a pair of high concentration source/drain regions 390a spaced apart from each other are provided in the active region of analog region A, and second gate pattern 340a is provided on a channel region between high-concentration source/drain regions 390a. A pair of low-concentration source/drain regions 380s are respectively provided below spacers 350 on both sidewalls of second gate pattern 340a, and low concentration source/drain regions 380s respectively contact high concentration source/drain regions 390a. Similarly, a pair of high concentration source/drain regions 390d spaced apart from each other are provided in the active region of digital region D, and third gate pattern 343d is disposed on a channel region between high concentration source/drain regions 390d. A pair of low concentration source/drain regions 380d are respectively provided below spacers 350 on both sidewalls of third gate pattern 343d, and low concentration source/drain regions 380d respectively contact high concentration source/drain regions 390d.

FIGS. 4 through 13 are related sectional views illustrating a method of fabricating an image sensor according to an embodiment of the invention.

Referring to FIG. 4, a semiconductor substrate 300 having an analog region A, a digital region D and a sensor region S is provided. An isolation layer 310 is formed in a predetermined region of semiconductor substrate 300. Isolation layer 310 defines active regions in analog region A, digital region D, and sensor region S, respectively. Isolation layer 310 may be formed using a shallow trench isolation technique.

Impurity ions 400 are implanted in analog region A of semiconductor substrate 300 to form an analog circuit well 320a, and impurity ions 410 are implanted in digital region D of semiconductor substrate 300 to form a digital circuit well 320d. Further, impurity ions 420 are implanted in sensor region S of semiconductor substrate 300 to form a sensor well 320s. In the illustrated embodiment, sensor well 320s is a p-type well. That is, impurity ions 420 are p-type impurity ions, such as boron (B) ions. This condition is assumed in the example because pixels to be formed in sensor region S are composed of NMOS transistors.

Analog circuit well 320a may be a p-type or n-type well. Similarly, digital circuit well 320d may be a p-type or n-type well. When analog circuit well 320a is p-type, the source/drain regions of an NMOS transistor constituting an analog circuit may be formed in analog circuit well 320a. On the contrary, when analog circuit well 320a is n-type, the source/drain regions of a PMOS transistor constituting an analog circuit may be formed in analog circuit well 320a. Similarly, when digital circuit well 320d is p-type, the source/drain regions of an NMOS transistor constituting a digital circuit may be formed in digital circuit well 320d. On the contrary, when digital circuit well 320d is n-type, the source/drain regions of a PMOS transistor constituting a digital circuit may be formed in digital circuit well 320d.

A p-type well may be formed by selectively implanting p-type impurity ions, such as boron (B) ions, into semiconductor substrate 300 at a dose of (e.g.,) about 3×1013 atoms/cm². Further, an n-type well may be formed by selectively implanting n-type impurity ions, such as phosphorus (P) ions, into semiconductor substrate 300 at a dose of (e.g.,) about 2×1013 atoms/cm².

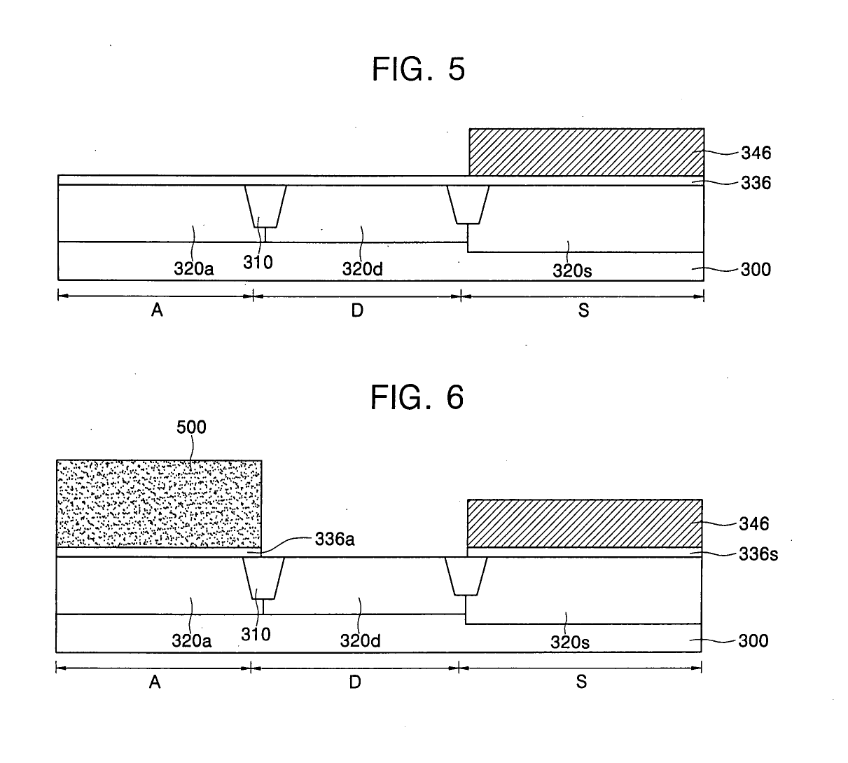

Referring to FIG. 5, a first gate insulating layer 336 is formed on semiconductor substrate 300 having wells 320s, 320a and 320d. First gate insulating layer 336 may be formed by thermally oxidizing semiconductor substrate 300 in an oxygen atmosphere. That is, first gate insulating layer 336 may be formed from a thermal oxide layer.

A first gate conductive layer is formed on first gate insulating layer 336, and patterned to form a first gate conductive layer pattern 346 covering sensor region S. The first gate conductive layer may be formed of a polysilicon layer.

Referring to FIG. 6, a first photoresist pattern 500 is formed on first gate insulating layer 336 to cover analog region A. First gate insulating layer 336 in digital region D is selectively removed using first photoresist pattern 500 and first gate conductive layer pattern 346 as etch masks. First gate insulating layer 336 in digital region D may be selectively removed using a wet etch process, or the like. As a result, the active region in digital region D is exposed, and first gate insulating layer pattern 336s is formed in sensor region S. Further, a second lower gate insulating layer 336a, which is composed of a portion of first gate insulating layer 336, remains in analog region A.

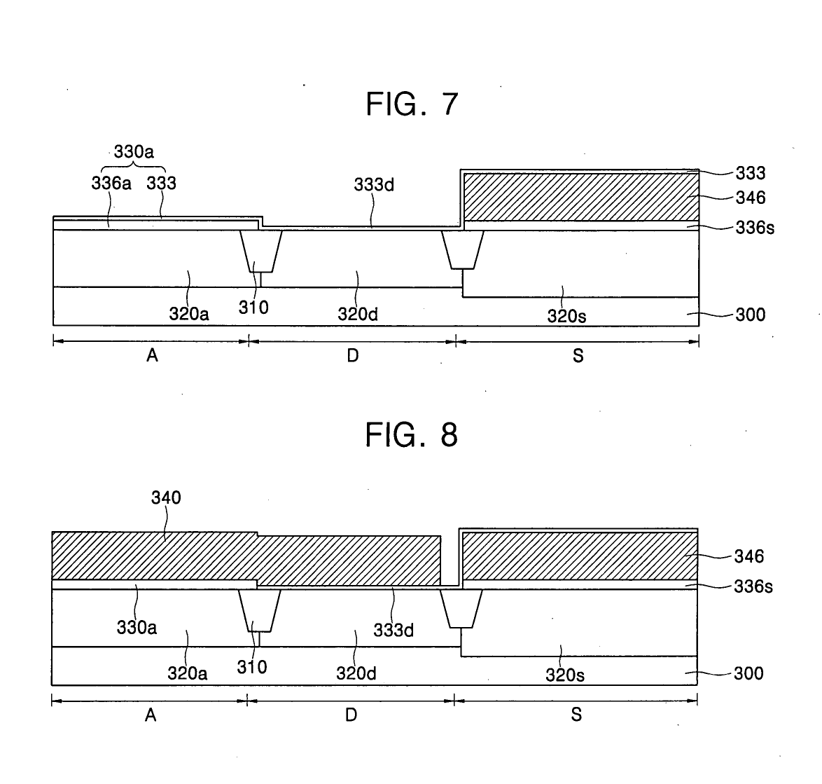

Referring to FIG. 7, first photoresist pattern 500 is removed. An additional gate insulating layer 333 is formed on semiconductor substrate 300 where first photoresist pattern 500 is removed. Additional gate insulating layer 333 may be formed of a silicon oxynitride layer. The silicon oxynitride layer may be formed, for example, by thermally treating semiconductor substrate 300 at a temperature of about 690° C. to 850° C. using a gas containing nitrogen (N) atoms and oxygen (O) atoms as an ambient gas. The gas containing nitrogen (N) atoms and oxygen (O) atoms may be an N2O gas or an NO gas, for example. Alternatively, the silicon oxynitride layer may be formed using a nitrogen plasma treatment process.

During formation of additional gate insulating layer 333, first gate conductive layer pattern 346 prevents first gate insulating layer pattern 336s in sensor region S from being exposed to the nitrogen atmosphere. Therefore, even though additional gate insulating layer 333 is formed of a silicon oxynitride layer, it can prevent first gate insulating layer pattern 336s from being nitrified. In other words, first gate conductive layer pattern 346 can prevent trap sites from being formed in first gate insulating layer pattern 336s during formation of additional gate insulating layer 333. As a result, first gate insulating layer pattern 336s remains in sensor region S without any nitrification, and second lower gate insulating layer 336a and additional gate insulating layer 333 thereon are formed in analog region A. Second lower gate insulating layer 336a and additional gate insulating layer on second lower gate insulating layer 336a constitute a second gate insulating layer 330a. Further, only additional gate insulating layer 333 is formed on the active region of digital region D. Therefore, first gate insulating layer 336s composed of only a pure silicon oxide layer may be formed in sensor region S, and second gate insulating layer 330a composed of a silicon oxide layer and a silicon oxynitride layer may be formed in analog region A. Further, a third gate insulating layer 333d composed of a silicon oxynitride layer may be formed in digital region D.

Referring to FIG. 8, a second gate conductive layer is formed on additional gate insulating layer 333. The second gate conductive layer may be formed of a polysilicon layer. Alternatively, the second gate conductive layer may be formed by sequentially stacking a polysilicon layer and a metal silicide layer. The second gate conductive layer is patterned to form a second gate conductive layer pattern 340 covering analog region A and digital region D.

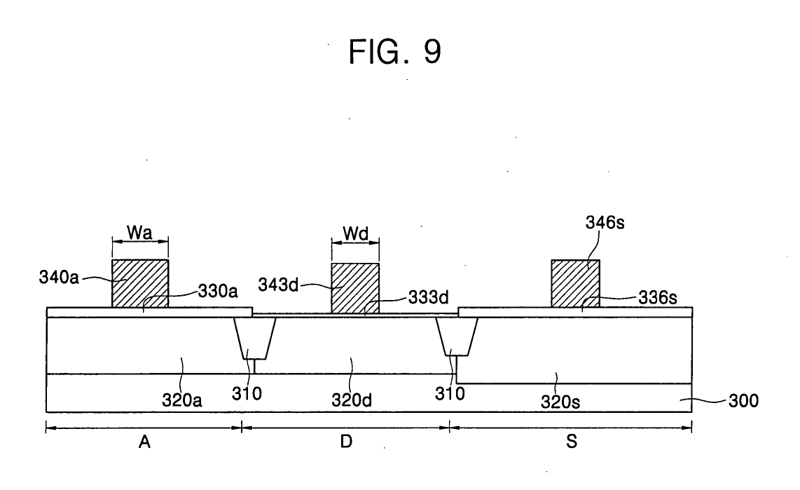

Referring to FIG. 9, the first and second gate conductive layer patterns 346 and 340 are patterned using photolithography and etch processes, thereby forming first through third gate patterns 346s, 340a and 343d. First through third gate patterns 346s, 340a and 343d are formed to cross over the active regions of sensor region S, analog region A and digital region D, respectively.

A width “Wa” of second gate pattern 340a formed in analog region A may be greater than a width “Wd” of third gate pattern 343d formed in digital region D. In one embodiment drawn to an image sensor having a design rule of 0.15 μm, third gate pattern 343d is formed to have a width of about 0.15 μm, and second gate pattern 340a is formed to have a width equal to or greater than about 0.25 μm.

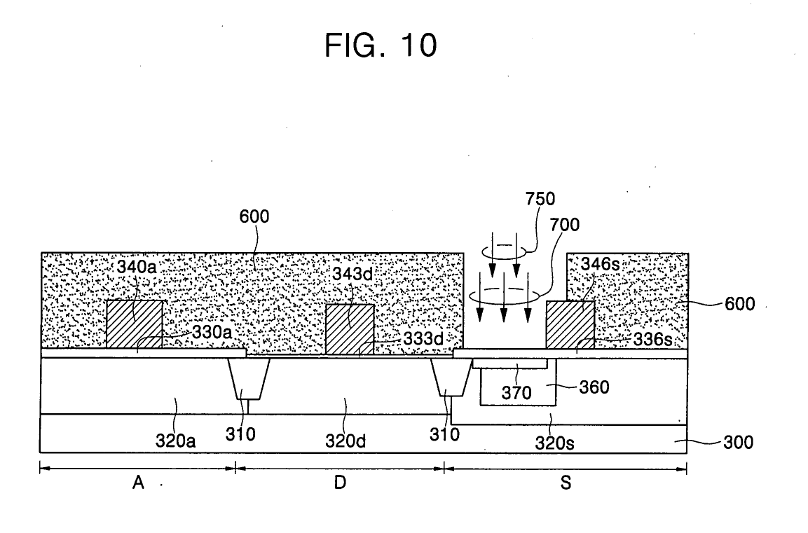

Referring to FIG. 10, a second photoresist pattern 600 is formed on the substrate having gate patterns 346s, 340a and 343d. Second photoresist pattern 600 is formed to have an opening exposing sensor well 320s adjacent to one sidewall of first gate pattern 346s.

N-type impurity ions 700, such as phosphoric (P) ions or arsenic (As) ions, are implanted into sensor well 320s using second photoresist pattern 600 as an ion implantation mask, thereby forming an n-type photodiode 360. Then, p-type impurity ions 750, such as boron (B) ions or boron fluoride (BF2) ions, are implanted into photodiode 360 using second photoresist pattern 600 and first gate pattern 346s as ion implantation masks, thereby forming a p-type HAD region 370. HAD region 370 may be formed using another photoresist pattern, which is different from second photoresist pattern 600, as an ion implantation mask.

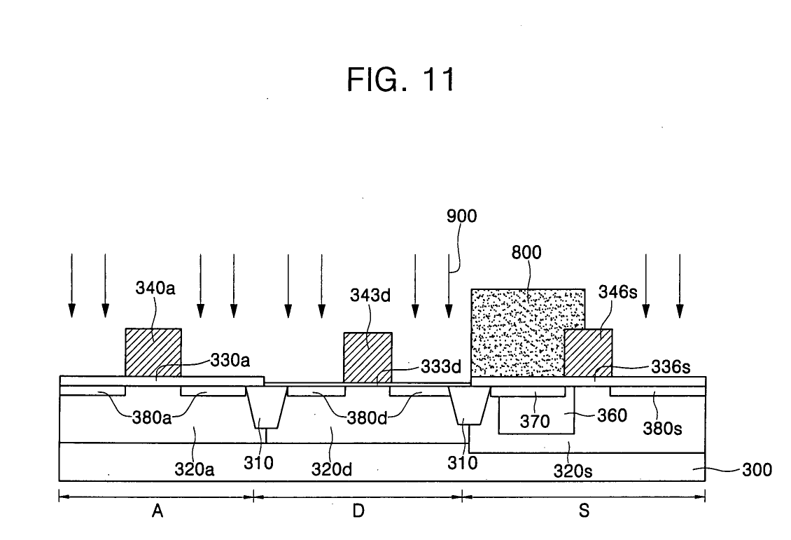

Referring to FIG. 11, second photoresist pattern 600 is removed. A third photoresist pattern 800 is formed on the substrate where second photoresist pattern 600 is removed. Third photoresist pattern 800 may be formed to cover HAD region 370 and at least a portion of first gate pattern 346s adjacent thereto. First gate pattern 346s corresponds to a transfer gate pattern of a unit pixel. Impurity ions 900 are implanted into the wells 320s, 320a and 320d using third photoresist pattern 800 as an ion implantation mask, thereby forming low-concentration source/drain regions 380s, 380a and 380d. In one embodiment, impurity ions 900 are implanted at a dose of about 1×1013 atoms/cm² to 5×1014 atoms/cm². Impurity ions 900 may be n-type impurity ions, such as phosphoric (P) ions or arsenic (As) ions. In this case, NMOS transistors are formed in analog region A and digital region D, as well as the sensor region S.

Although not shown in the illustrated embodiments, those of ordinary skill will understand that p-type impurity ions, such as boron (B) ions or boron fluoride (BF2) ions, may be selectively implanted into PMOS transistor regions of analog region A and digital region D in order to form PMOS transistors in these regions. In this case, p-type low-concentration source/drain regions may be formed. Low-concentration source/drain regions 380s, 380a and 380d may be self-aligned with gate patterns 346s, 340a and 343d.

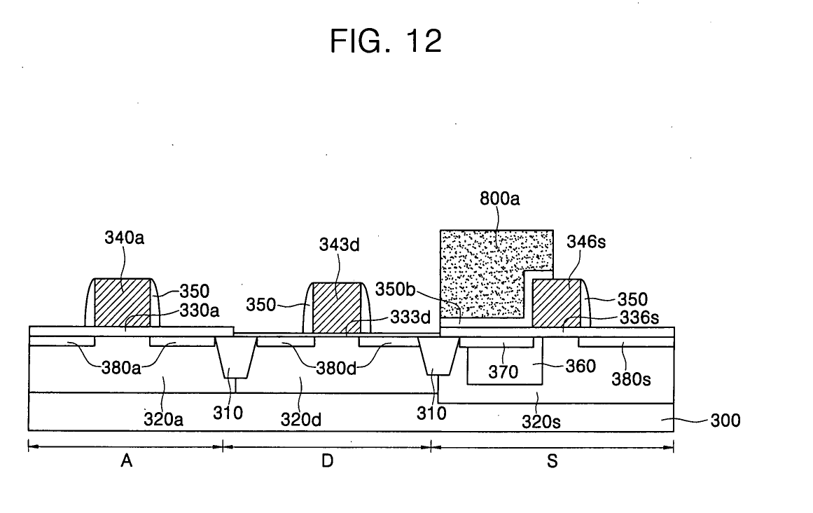

Referring to FIG. 12, third photoresist pattern 800 is removed. An insulating layer such as a silicon nitride layer is formed on the substrate where third photoresist pattern 800 is removed. A fourth photoresist pattern 800a having the same configuration as third photoresist pattern 800 shown in FIG. 11 is then formed on the insulating layer. The insulating layer is anisotropically etched using fourth photoresist pattern 800a as an etch mask. As a result, spacers 350 are formed on the sidewalls of gate patterns 340a, 343d and 346s, and a blocking layer 350b is formed to cover HAD region 370 and one sidewall of first gate pattern 346s adjacent thereto. Blocking layer 350b is formed to prevent impurities, such as metal ions, from being introduced into photodiode 360 during formation of spacers 350.

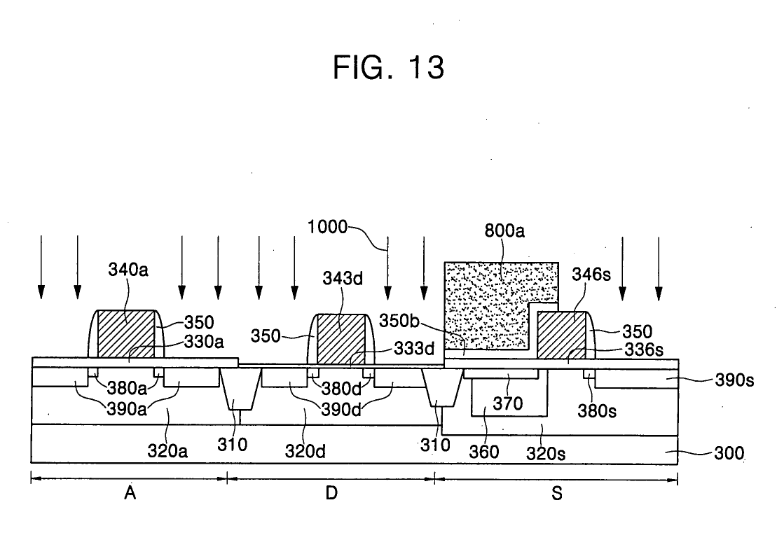

Referring to FIG. 13, impurity ions 1000 are implanted into wells 320s, 320a and 320d using fourth photoresist pattern 800a, gate patterns 340a, 343d and 346s, and spacers 350 as ion implantation masks, thereby forming high-concentration source/drain regions 390s, 390a and 390d. In one embodiment, impurity ions 1000 may be implanted at a dose of about 1×1015 atoms/cm² to 9×1015 atoms/cm². Impurity ions 1000 may be n-type impurity ions, such as phosphoric (P) ions or arsenic (As) ions. In this case, NMOS transistors are formed in analog region A and digital region D, as well as sensor region S.

When blocking layer 350b is formed to a sufficient thickness to be used as an ion implantation mask during implantation of impurity ions 1000, impurity ions 1000 may be implanted after removal of fourth photoresist pattern 800a.

Although not shown in the illustrated embodiments, p-type impurity ions, such as boron (B) ions or boron fluoride (BF2) ions, may be selectively implanted into the PMOS transistor region of analog region A and digital region D in order to form PMOS transistors in these regions. In this case, p-type high-concentration source/drain regions may be formed. The high-concentration source/drain regions 390a, 390d and 390s may be self-aligned with the spacers 350.

According to the embodiments described above, an image sensor is provided having multi-gate insulating layers suitable for the respective formation of transistors in sensor, digital, and analog regions of a substrate. Thus, generation of noise in the sensor region may be suppressed, and high performance transistors may be formed in analog and digital regions.

While the present invention has been particularly shown and described with reference to exemplary embodiments, it will be understood by those of ordinary skill in the art that various changes in form and details may be made therein without departing from the scope of the invention as defined by the following claims.

What is claimed is:

1. An image sensor comprising:
a first gate insulating layer of first material layer type disposed in a sensor region of a semiconductor substrate;
a second gate insulating layer of second material layer type disposed in an analog region of the semiconductor substrate; and
a third gate insulating layer of third material layer type disposed in a digital region of the semiconductor substrate;
wherein the first, second, and third material layer types are disparate.

2. The image sensor according to claim 1, wherein the first material layer type is silicon oxide.

3. The image sensor according to claim 2, wherein the second material layer type is a combination of silicon oxide and silicon oxynitride, and the third material layer type is silicon oxynitride.

4. The image sensor according to claim 1, wherein the sensor region comprises photodiodes.

5. The image sensor according to claim 1, wherein the digital region comprises a timing generator, a row decoder, a row driver, a latch unit, a column decoder and an image signal processor.

6. The image sensor according to claim 1, wherein the analog region comprises a correlated double sampler (CDS) and an analog to digital converter (ADC).

7. The image sensor according to claim 1, wherein the third material layer type is thinner than the first and second material layer types.

8. The image sensor according to claim 7, wherein the second material layer type is thicker than the first material layer type.

9. The image sensor according to claim 7, wherein a thickness for the second material layer type ranges between about two to four times a thickness for the third material layer type.

10. The image sensor according to claim 7, wherein the first material layer type comprises a nitrogen-free silicon oxide layer.

11. The image sensor according to claim 10, wherein the second material layer type is a combination of silicon oxide layer and silicon oxynitride, and the third material layer type is silicon oxynitride.

12. A method of fabricating an image sensor, comprising:
forming a first gate insulating layer on a substrate;
forming a first gate conductive layer pattern on the first gate insulating layer in a sensor region of the substrate;
selectively removing the first gate insulating layer from a digital region of the substrate;
forming an additional gate insulating layer on the substrate where the first gate insulating layer has been selectively removed from the digital region of the substrate, wherein the first gate insulating layer and the additional gate insulating layer in an analog region of the substrate form a second gate insulating layer, and the additional gate insulating layer in the digital region of the substrate form a third gate insulating layer; and
forming a second gate conductive layer pattern to cover the additional gate insulating layer in the analog and digital regions.

13. The method according to claim 12, wherein the first gate insulating layer is formed of a silicon oxide layer.

14. The method according to claim 13, wherein the additional gate insulating layer is formed of a silicon oxynitride layer.

15. The method according to claim 14, wherein the silicon oxynitride layer is formed using a thermal treatment process that employs a gas containing nitrogen atoms and oxygen atoms.

16. The method according to claim 14, wherein the silicon oxynitride layer is formed using a nitrogen plasma treatment process.

17. The method according to claim 12, further comprising patterning the first gate conductive layer pattern and the second gate conductive layer pattern to form first through third gate patterns in the sensor region, the analog region and the digital region respectively.

18. The method according to claim 17, further comprising forming a photodiode in the semiconductor substrate of the sensor region adjacent to one sidewall of the first gate pattern.

19. The method according to claim 18, further comprising forming spacers on sidewalls of the gate patterns.

20. The method according to claim 19, wherein forming the spacers comprises:
forming a spacer layer on the substrate having the photodiode; and
anisotropically etching the spacer layer.

21. The method according to claim 19, wherein forming the spacers comprises:
forming a spacer layer on the substrate having the photodiode;
forming a mask pattern on the spacer layer to cover the photodiode; and
anisotropically etching the spacer layer using the mask pattern as an etch mask, wherein a blocking layer composed of a portion of the spacer layer remains under the mask pattern while the spacer layer is anisotropically etched.

22. The method according to claim 21, further comprising implanting impurity ions into the semiconductor substrate using the gate patterns, the blocking layer and the spacers as ion implantation masks to form source/drain regions.
